(19) United States
(12) Patent Application Publication
(10) Pub. No.: US 2025/0301845 A1
(43) Pub. Date: Sep. 25, 2025

(54) VERTICAL OPTICAL IO FOR MULTI-CHIP PACKAGES

(71) Applicants: Robert Kalman, Sunnyvale, CA (US); Sunghwan Min, Sunnyvale, CA (US); Howard Rourke, Sunnyvale, CA (US); Jonathan Liu, Sunnyvale, CA (US); Bardia Pezeshki, Sunnyvale, CA (US); Ivan Huang, Sunnyvale, CA (US); Alexander Tselikov, Sunnyvale, CA (US)

(72) Inventors: Robert Kalman, Sunnyvale, CA (US); Sunghwan Min, Sunnyvale, CA (US); Howard Rourke, Sunnyvale, CA (US); Jonathan Liu, Sunnyvale, CA (US); Bardia Pezeshki, Sunnyvale, CA (US); Ivan Huang, Sunnyvale, CA (US); Alexander Tselikov, Sunnyvale, CA (US)

(21) Appl. No.: 19/088,685

(22) Filed: Mar. 24, 2025

Related U.S. Application Data
(60) Provisional application No. 63/569,365, filed on Mar. 25, 2024.

(51) Int. Cl. H10H 29/85; H01L 25/16; H10H 29/854

(52) U.S. Cl. CPC H10H 29/8506; H01L 25/167; H10H 29/854; H10H 29/857

(57) ABSTRACT

A multi-chip package may include a system-on-chip (SoC) and an optical IO subassembly on a common substrate. The SoC and the optical IO subassembly may be linked by a die-to-die interface. The optical IO subassembly may include an optical IO IC with microLEDs and/or photodetectors bonded to a surface of the optical IO IC away from the common substrate. An optical window layer may shield optical elements of the optical IO subassembly from damage relating to molding compound related operations during assembly.

### CROSS-REFERENCE TO RELATED APPLICATIONS

This application claims the benefit of U.S. Provisional Patent Application No. 63/569,365, filed on Mar. 25, 2024, the disclosure of which is incorporated by reference herein.

### BACKGROUND OF INVENTION

The need for high-performance computing and networking is ubiquitous and ever-increasing. Prominent applications include data center servers, high-performance computing clusters, artificial neural networks, and network switches.

Processing capabilities of integrated circuits (ICs) have been advancing faster than their IO for decades. This has resulted in problems such as the “memory wall,” where the performance of processing systems is limited to far less than optimum due to memory IO limitations.

A single IC can only contain so much functionality based on transistor count and power constraints. Additionally, different functions (e.g. logic, DRAM, I/O) require different process sequences, and thus not all the desired functions can be combined on a single integrated circuit.

In fact, there are significant benefits to “de-integrating” SoCs into smaller “chiplets”, including: the process for each chiplet can be optimized to its function, e.g. logic, DRAM, high-speed I/O, etc.; chiplets are well-suited to reuse in multiple designs; chiplets are less expensive to design; chiplets have higher yield because they are smaller with fewer devices.

However, a major drawback to chiplets compared to SoCs is that chiplets require a higher density of inter-chip connections. Compared to the on-chip connections between functional blocks in SoCs, chip-to-chip connections are typically much less dense and require far more power (normalized as energy per bit).

State-of-the-art chip-to-chip interconnects utilize interposers and bridges, where the chips are flip-chip bonded to a substrate that contains the chip-to-chip electrical traces. While such interconnects provide far higher density and far lower power than interconnects of packaged chips via a printed circuit board (PCB), they still fall very far short of what is desired: chip-to-chip interconnects that approach the density and power dissipation of intra-chip interconnects.

The power and maximum reach of electrical interconnects are fundamentally limited by capacitance and conductor resistance. Interconnect density is limited by conductor width and layer count. The capacitance C of short electrical interconnects is proportional to interconnect length and approximately independent of conductor width w (assuming dielectric thickness scales approximately proportionately). The resistance R of electrical connections, and thus the maximum length (limited by RC) is inversely proportional to the conductor cross-sectional area, which scales as w². The density of electrical connections is inversely proportional to w. Thus, there are trade-offs in interconnect density, length, and power, and these trade-offs are fundamental, being based on dielectric permittivity and conductor (e.g. copper) resistance.

Thus electrical interconnects have fundamental limitations that constrain system performance and limit what is achievable with so-called “more than Moore” 2.5D and 3D advanced packaging.

### BRIEF SUMMARY OF THE INVENTION

Multi-chip packages comprise multiple interconnected ICs within a single package. Vertical optical IO interfaces mounted to one or more of the ICs provide the potential for external MCP connections that are tens of centimeters or multiple meters long with very high IO density with low power dissipation. Vertical optical IO interfaces that are compatible with standard advanced electrical multi-chip packaging architectures and assembly processes are discussed herein. Such interfaces enable use of existing high-volume manufacturing capabilities.

Some embodiments in accordance with aspects of the invention provide a multi-chip package with a vertical optical interface, comprising: a base substrate; a system-on-chip (SoC) on the base substrate; an optical IO subassembly on the base substrate, the optical IO subassembly coupled to the SoC by a die-to-die (D2D) interface; with the optical IO subassembly comprising an optical IO IC mounted to the base substrate, optoelectronic (OE) device arrays bonded to a surface of the optical IO IC away from the base substrate, and, over the OE device arrays, coupling optics to increase optical coupling efficiency into optical fibers, and an optical window layer.

In some embodiments the optical window layer is over the coupling optics. In some embodiments the D2D interface traverses the base substrate. In some embodiments the OE device arrays comprise arrays of microLEDs and/or photodetectors. In some embodiments the OE device arrays comprise arrays of microLEDs. In some embodiments the optical IO IC includes LED driver circuitry for driving the microLEDs. In some embodiments the SoC and the optical IO IC are in a layer of molding compound. In some embodiments the optical window layer comprises an optical microchannel window. In some embodiments the optical microchannel window comprises fiber cores. In some embodiments the optical microchannel window duplicates an optical distribution presented at one face of the optical microchannel window at another face of the optical microchannel window. In some embodiments the optical microchannel window comprises cores on a grid matching a grid of the microLEDs. In some embodiments the optical window layer comprises a clear uniform optical medium.

These and other aspects of the invention are more fully comprehended upon review of this disclosure.

### BRIEF DESCRIPTION OF THE FIGURES

FIGS. 1a-b illustrate a side view and a top view of a multi-chip package, respectively, in accordance with aspects of the invention.

FIG. 2 shows a cross-section of an embodiment of a fiber bundle.

FIG. 3 shows an embodiment of an SoC connected to an optical IO subassembly in a multi-chip package.

FIG. 4 shows an embodiment of an SoC connected to an optical IO subassembly with in a multi-chip package where an additional IO logic IC is used for communication between the SoC and the optical IO IC of the optical IO subassembly.

FIG. 5 shows an embodiment of an optical IO subassembly with an optical window layer comprising an optical microchannel window.

FIG. 6 FIG. 6 shows another embodiment of an optical IO subassembly with an optical window.

FIG. 7 shows an embodiment in which the optical window layer comprises a clear uniform optical medium.

FIG. 8 shows an idealized view of an example implementation in accordance with aspects of the inventions.

### DETAILED DESCRIPTION

The inventions discussed herein relate to implementations of vertical optical input/output (IO) interfaces within multi-chip packages (MCPs). An MCP comprises multiple integrated circuits (ICs or “chips”) that are electrically interconnected to each other and to an external printed circuit board (PCB) via a package substrate. The package substrate comprises one or more layers of electrical traces, with vias connecting between layers and to the two outside surfaces.

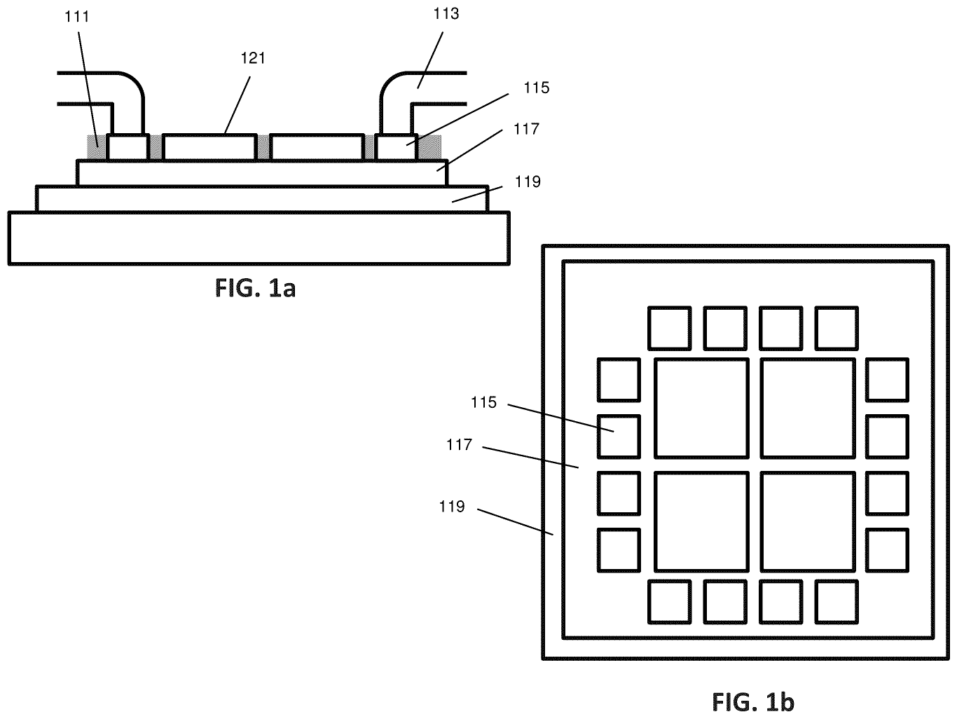

FIGS. 1a and 1b illustrate a side view and a top view, respectively, of a multi-chip package. The MCP may comprise a diversity of ICs, such as complex system-on-chips (SoCs) 121 that comprise primarily processing or digital switching functionality, for example as shown in FIGS. 1a,b. Examples of processing SoCs are central processing units (CPUs), graphical processing units (GPUs), data processing units (DPUs), tensor processing units (TPUs), and network processing units (NPUs). An MCP may also comprise ICs 115 that provide IO functionality (“IO ICs”) that allow ICs within the MCP to communicate with ICs outside of the MCP. If these ICs are small, for instance with a footprint of <5 mm×5 mm, they are sometimes called “chiplets.”

An MCP may comprise an additional interposer layer 117. The SoCs and IO ICs may be mounted to the interposer layer. The interposer typically comprises a silicon substrate with one or more layers of electrical traces, with vias connecting between layers of traces. The interposer also comprises through-silicon vias (TSVs) providing connectivity between the two surfaces of the interposer substrate. The interposer is electrically connected to the package substrate by solder bumps, for instance, controlled collapse chip connection (C4) bumps.

The process for assembling ICs onto an interposer may include application of molding compound on top of and between the ICs. The molding compound is typically comprised of a polymer material. In a subsequent process step, the molding compound is ground down to expose the top surface of the ICs, for example to allow a low thermal resistance to any heat sink applied on top of the ICs. The use of molding compound can contaminate optical interfaces if inventions such as those described herein are not utilized.

ICs within an MCP may connect to each other via die-to-die (D2D) interfaces. High-performance D2D interfaces typically have a reach of <25 mm, often <10 mm, with power dissipation of <1 pJ/bit. The demands of HPC and AI/ML systems are driving D2D interfaces to data densities of >1 Tbps/mm. Some examples of D2D interfaces are UCIe, HBM4, bunch-of-wires (BoW), XSR, USR, LIPINCON, and Infinity Fabric.

The interposer is on a package substrate 119. The package substrate may comprise one or more layers of electrical traces, with vias connecting between layers and to the two outside surfaces. The package substrate may be on, for example, a printed circuit board 123.

Some IO ICs may be part of an optical IO subassembly that comprises one or more ICs, and optical interfaces coupled to optical transmission media such as optical fibers. In some embodiments of the inventions described herein, an optical interface comprises one or more optical emitters and/or detectors where the primary direction of light propagation is normal to the plane of the IO IC(s). The term “optoelectronic device” (or “OE device”) will be used to refer to either an optical emitter or photodetector (PD).

In some further embodiments, the OE devices in an optical IO subassembly comprise one or more arrays of optical emitters, where the OE devices comprising an array are located on some regular geometric grid, e.g. a rectangular or hexagonal close-packed grid. Examples optical emitters comprising these arrays are microLEDs and vertical cavity surface-emitting lasers (VCSELs). Examples of photodetectors comprising these arrays are p-i-n photodetectors (PDs) and avalanche photodetectors (APDs).

In some embodiments comprising microLED emitters, a microLED is made from a p-n junction of a direct-bandgap semiconductor material. In some embodiments a microLED is distinguished from a semiconductor laser (SL) as follows: (1) a microLED does not have an optical resonator structure; (2) the optical output from a microLED is almost completely spontaneous emission, whereas the output from a SL is dominantly stimulated emission; (3) the optical output from a 15 microLED is temporally and spatially incoherent, whereas the output from a SL has significant temporal and spatial coherence; (4) a microLED is designed to be driven down to a zero minimum current, whereas a SL is designed to be driven down to a minimum threshold current, which is typically at least 1 mA. In some embodiments a microLED is distinguished from a standard LED by (1) having an emitting region of less than 10 μm×10 μm; (2) frequently having cathode and anode contacts on top and bottom surfaces, whereas a standard LED typically has both positive and negative contacts on a single surface; (3) typically being used in large arrays for display and interconnect applications. In some embodiments, each microLED is made from the GaN material system with InGaN quantum wells. In some embodiments, each microLED is made from the GaAs or InP material system.

In the example of FIGS. 1a,b, System-on-chip (SOC) ICs 121 are mounted on the interposer 117, with optical IO subassemblies 115 also mounted on the interposer. The ICs and the optical IO sub-assemblies may be in molding compound 111. Multi-channel optical transmission media 113, for example in the form of or including multicore fiber bundles, are coupled to the optical IO subassemblies so as to receive light from the optical emitters and/or pass light to the optical detectors.

In some embodiments, an optical IO subassembly comprises OE devices that are coupled into multi-channel optical transmission media. In some embodiments, the optical transmission media comprise of one or more fiber bundles. A fiber bundle comprises multiple fiber elements, where each fiber element comprises a core surrounded by a concentric cladding. In some further embodiments, the space between the fiber elements may contain some filler material, while in other embodiments the space between fiber elements is empty. In some embodiments, the fiber elements are attached to each other only at the ends of the fiber and are unattached “loose” fiber elements between the ends. In some embodiments, the diameter of the cores is in the range of 25 μm to 50 μm. In some embodiments of a fiber bundle, the cores are located on a regular geometric grid. In some embodiments, this grid is square. In some embodiments, the cores are in a hexagonal close-packed (HCP) configuration such that they lie on a equilateral triangular grid. In some embodiments, the cores of a bundle are not on a regular grid.

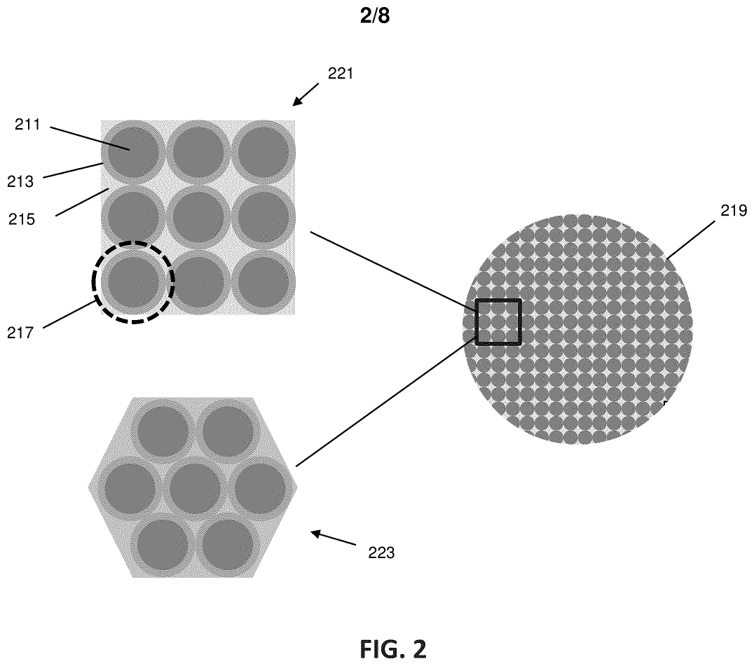

A cross-section of an embodiment of a fiber-optic bundle 219 is shown in FIG. 2. The coherent fiber bundle includes a plurality of cores 211 for the transmission of light. Each core is surrounded by a concentric cladding layer 213 that has a lower index of refraction than the core. Each core and corresponding concentric cladding layer together may be considered a fiber element 217. The space around the fiber elements may be filled with a filler material 215. In some embodiments, the fibers may be arranged in a regular pattern, such as on a square grid 221 or hexagonal grid 223. In some embodiments of a fiber-optic bundle, the positions of each fiber element relative to the other fiber elements are the same at each end of the fiber bundle such that relative positions of the fiber elements are preserved at each end. A fiber-optic bundle in which the relative positions of the fiber elements are preserved is referred to as a “coherent” fiber-optic bundle.

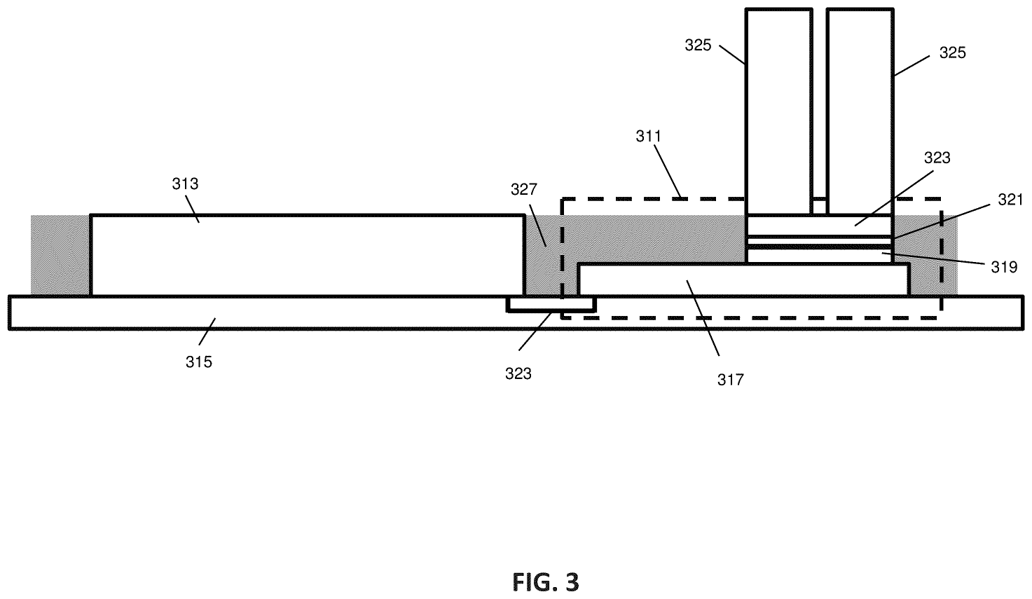

FIG. 3 shows an embodiment of an SoC 313 connected to an optical IO subassembly 311 in a multi-chip package. Both the optical IO assembly and the SoC are attached to a base substrate 315 (for instance, a Si interposer or package substrate) by solder bumps, for instance C4 solder bumps. An optical IC 317 of the optical subassembly is coupled to the SoC by a D2D interface 323 routed through the base substrate. The D2D interface may be considered a “horizontal” D2D interface that traverses the base substrate.

The optical IO subassembly may include the optical IO IC 317, OE device arrays 319, coupling optics 321, and, in some embodiments, an optical window layer 323. The optical IO IC is mounted to the base substrate. The optical IO IC may include a D2D interface for receiving and/or providing information to the SoC. The optical IO IC may also include LED driver circuitry for driving microLEDs based on information provided by the SOC, if the OE device arrays include microLEDs. The optical IO IC may also include receive circuitry, for example including transimpedance amplifiers (TIAs), if the OE device arrays include photodetectors. The OE device arrays may be bonded to a surface of the optical IO IC away from the base substrate. The IO IC may include TSVs that connect a surface of the IO IC mounted to the base substrate with active electronic devices are closer to the surface of the IO IC away from the base substrate.

Light to or from the OE device arrays are coupled into or out of fiber bundles 325. The fiber bundles may each include a plurality of optical fibers. In some embodiments there is a one-to-one correspondence between optical devices of the OE device arrays and optical fibers. Coupling optics may be over or attached to the OE devices to increase optical coupling efficiency to the rest of the optical interconnect, for example the optical fibers. The coupling optics may include, for example, an array of lenses.

The SoC and optical IO IC are shown as being in a layer of molding compound 327 on the base substrate. The molding compound, or any grinding or reduction of the molding compound, potentially may interfere with optical elements of the optical subassembly. The optical subassembly of FIG. 3 includes an optical window layer 323 between the coupling optics and the fiber bundles, which in some embodiments are attached to optical IO subassembly after other components of the device of FIG. 3 are assembled. In some embodiments the optical window layer serves to protect the other optical elements of the optical subassembly during application and/or processing of the molding compound.

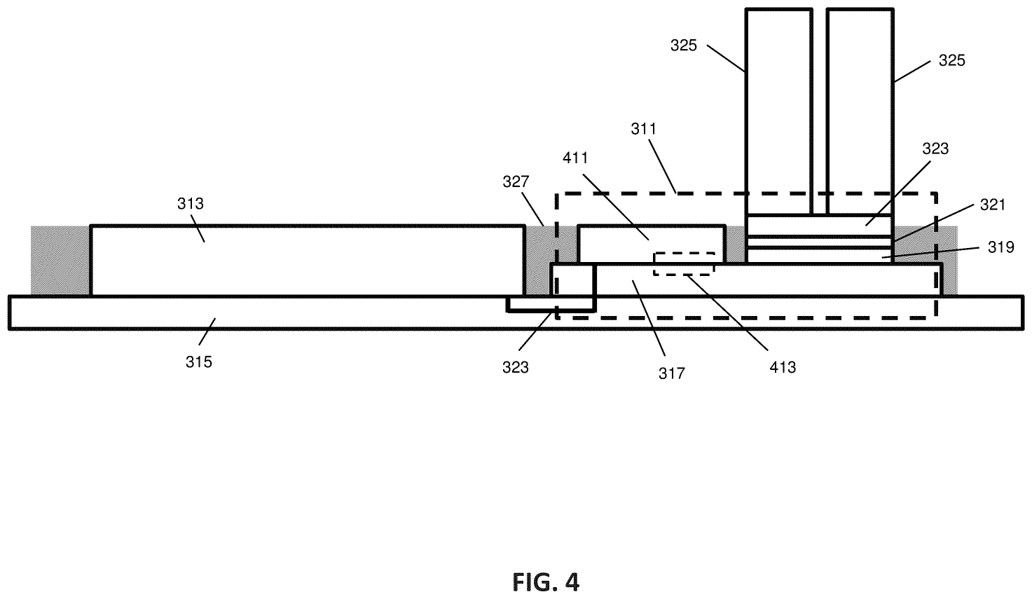

FIG. 4 shows another embodiment of an SoC connected to an optical IO subassembly with an MCP where an additional IO logic IC 411 is used for communication between the SoC 313 and the optical IO IC 317. The embodiment of FIG. 4 is the same as that of FIG. 3, except that the additional IO logic IC is used. In FIG. 4, the additional IO logic IC is shown as attached to the optical IO IC, with the IO logic IC mounted on the surface of the optical IO IC away from the base substrate 315. The horizonal D2D connection 323 with the SoC terminates on the IO logic IC, which has the D2D interface circuitry for that connection, instead of the optical IO IC having that circuitry. In turn, the IO logic IC and the optical IO IC have D2D circuitry for a vertical D2D interface 413 providing electrical connections between the IO logic IC and the optical IO IC.

A benefit of this architecture, relative to that of the embodiment of FIG. 3, is that horizontal D2D interfaces typically are implemented in a very advanced, expensive IC node (for instance, <5 nm CMOS). By contrast, the optical IO IC can often be implemented in an older, less expensive node (e.g. >16 nm CMOS).

In some embodiments, the OE device arrays are coupled to a multi-channel optical transmission medium via an “optical window” layer. One purpose of the optical window layer is to allow light to propagate to/from the OE device arrays to the fiber bundles while protecting the OE device arrays during package assembly/processing.

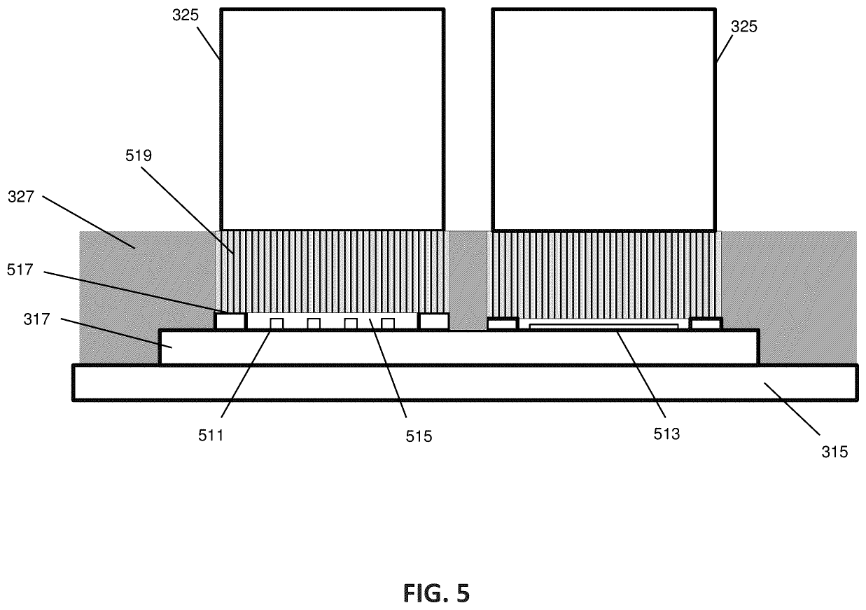

FIG. 5 shows an embodiment of an optical IO subassembly with an optical window layer comprising an optical microchannel window. In FIG. 5, an optical IO IC 317 is on a base substrate 315. A microLED array, for example including microLED 511, is on a surface of the optical IO subassembly away from the base substrate. A photodetector array 513 is also on the surface of the optical IO subassembly away from the base substrate. Fiber bundles 325 are positioned to be in optical communication with the microLED array and the photodetector array.

Gaskets, e.g., gasket 517 for the microLED array, laterally encompasses each of the microLED array and the photodetector array. An optical window, e.g., optical window 519 for the microLED array, is attached to each gasket. The optical window creates a very small gap (often <5 μm) between the optical window and the OE device array elements, for instance, microLEDs or PDs. An index matching medium, e.g., index matching medium 515 for the microLED array, in this small gap minimizes reflections at the optical window interface. Molding compound 327 is on top of the base substrate and over the optical IO IC.

In some embodiments, assembly of the MCP comprises: OE device arrays are attached to optical IO ICs, gaskets and optical windows are attached to the optical IO ICs, the optical IO ICs and SoCs are attached to an interposer or package substrate by solder bumps, molding compound is applied to the substrate and over the ICs, and planar grinding is performed to grind away the molding compound until the molding compound has been ground away over all of the ICs and optical windows.

This molding compound application and grinding processes are part of standard MCP assembly. By utilizing optical windows (which may also be termed frames or plates) covering the OE device arrays, the optical interfaces are protected while enabling compatibility with standard MCP processing.

In some embodiments, an optical microchannel window or plate comprises small optical fiber cores, often <50 μm in diameter, packed tightly and separated by a small amount cladding material. An optical distribution presented at one face of the microchannel plate is duplicated at the other face.

In some embodiments, an optical microchannel window or plate comprises small optical fiber cores (often <20 μm core diameter) that are densely packed such that the light from each optical emitter couples to multiple cores or each PD receives light from multiple cores.

In some embodiments, the optical microchannel window or plate comprises optical cores on a grid spacing that is matched to that of the optical emitters or PDs. For instance, an array of microLED emitters or PDs may be on a 50 μm spacing hexagonal close-spaced (HCP) grid, and the microchannel plate may comprise cores that are in diameter that are located on a 50 μm HCP grid matching that of the emitter or PD array.

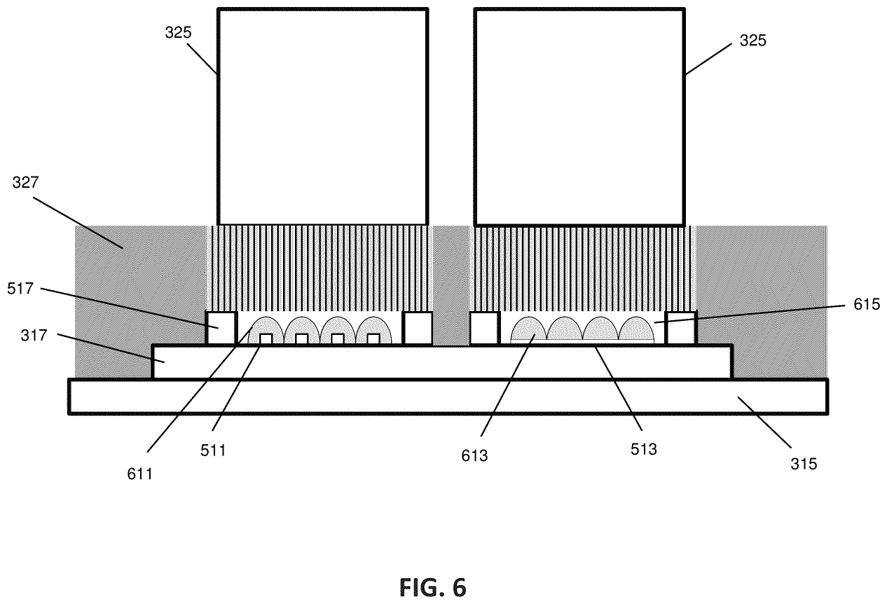

FIG. 6 shows another embodiment of an optical IO subassembly with an optical window comprising an optical microchannel window. The embodiment of FIG. 6 is generally as discussed with respect to the embodiment of FIG. 5. As compared to the embodiment of FIG. 5, however, the embodiment of FIG. 6 is shown as including microlenses 611, 613 for the microLEDs and photodetectors, respectively, and provides an air gap between the OE devices/microlenses and the optical window. The air gap is in place of the index matching material, and serves to enable the microlenses to bend the light for optimizing optical coupling efficiency into the optical window layer and into the fiber bundles.

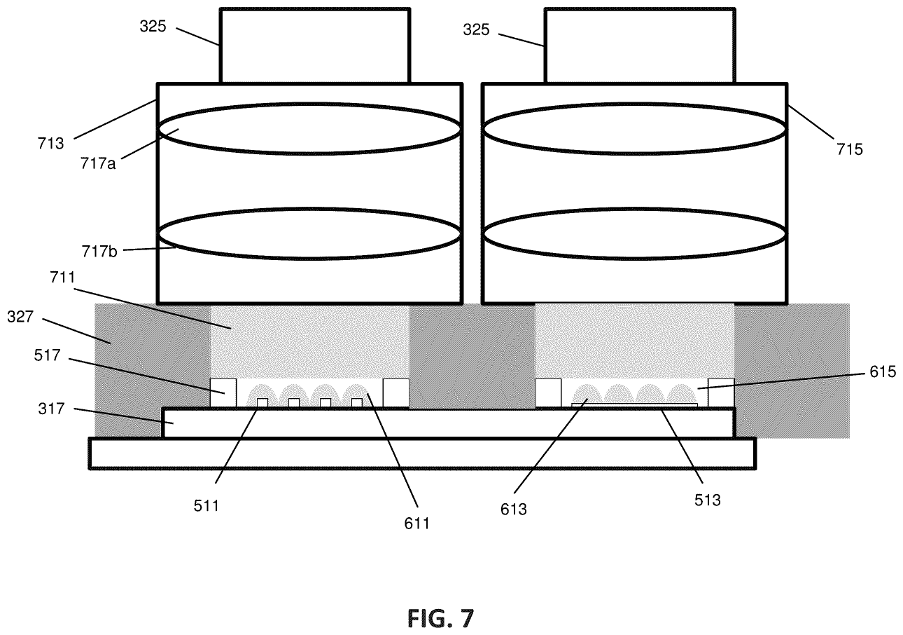

FIG. 7 shows a similar embodiment, with like items numbered as in prior FIGs., to which reference may be had. In the embodiment of FIG. 7, the optical window layer comprises a clear uniform optical medium 711. In some further embodiments, and as also illustrated in FIG. 7, an optical coupling assembly 713, 715 is between the optical window layer and the fiber bundles for each of the microLED array and the photodetector array, respectively. The optical coupling assembly may be attached to the optical window layer. The optical coupling assembly comprises one or more lenses and/or mirrors. The optical window layer and optical coupling assembly images an OE device array onto the end face of the optical transmission medium.

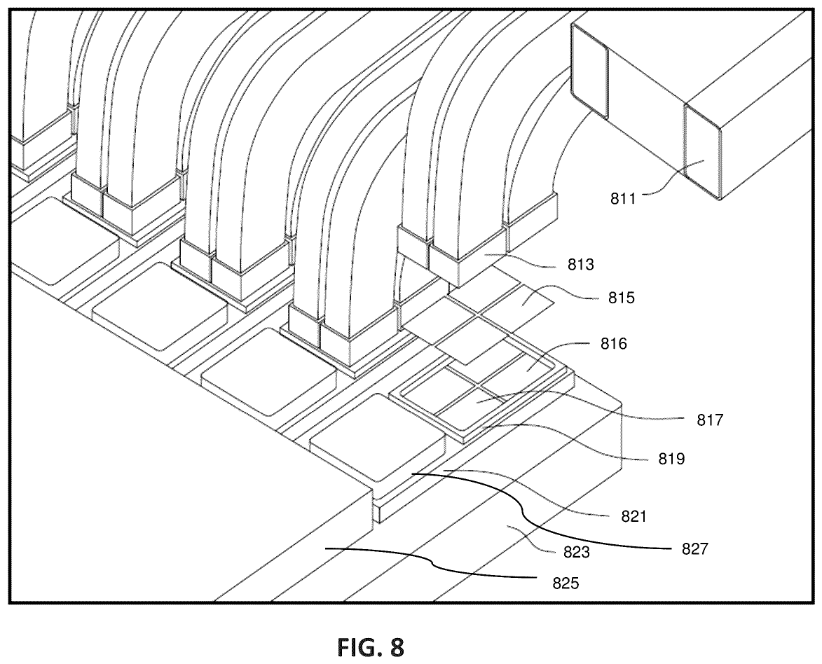

FIG. 8 shows an idealized view of an example implementation in accordance with aspects of the inventions. A GPU 825 is mounted to a silicon interposer 823. The interposer may be in a multi-chip module package, for example. A chiplet 821 is also mounted to the silicon interposer. The GPU and the chiplet are in electronic communication with each other through electrical signal pathways of the interposer.

The chiplet includes electrical signal pathways from a surface mounted to the interposer to an area of an opposing surface of the chiplet. A die-to-die (D2D) interface chip 827 is mounted to the area of the opposing surface. The TSVs allow for communication between the D2D interface chip and the GPU. The D2D interface and the GPU may each have D2D interface circuitry, for example interface circuitry compliant with a Universal Chiplet Interconnect Express (UCIe) specification.

The chiplet also includes LED driver circuitry and receive circuitry, for example including transimpedance amplifiers (TIAs). The LED driver circuitry may be uLED driver circuitry. The chiplet also includes electrical signal pathways between the area of the opposing surface and the LED driver circuitry and receive circuitry. In some embodiments the electrical signal pathways may include buffers in an active layer of the chiplet. The LED driver circuitry and receive circuitry may also be in the active layer of the chiplet.

The driver circuitry is configured to drive LEDs 817. The LEDs are shown as bonded to the opposing surface of the chiplet. Photodetectors 816 are also bonded to the opposing surface of the chiplet. In some embodiments the photodetectors may be in a layer bonded to the chiplet, with the LEDs bonded to that layer. The photodetectors are coupled to the receive circuitry.

The LEDs 817 and photodetectors 816 are each shown as being arranged in arrays, within a frame 819. A fiber bundle 811 including a plurality of multicore fibers is mounted to each of the arrays. Each fiber bundle is comprised of a plurality of fibers. In some embodiments there is a one-to-one correspondence between LEDs and fibers of a bundle. In some embodiments there is also a one-to-one correspondence between photodetectors and fibers of a bundle. The fiber bundles are also shown with a ferrule 813 about their end, for mounting to the frame. In such embodiments, the ferrule may be used to mounting to the fiber plate or the frame. In between ends of the fibers and the LED and photodetectors are lens arrays 815. The lenses of the lens arrays focuses light from the LEDs into the fibers, and focuses light from the fibers onto the photodetectors.

Although the inventions have been discussed with respect to various embodiments, it should be recognized that the inventions comprise the novel and non-obvious claims supported by this disclosure.

What is claimed is:

1. A multi-chip package with a vertical optical interface, comprising:
a base substrate;
a system-on-chip (SoC) on the base substrate; and
an optical IO subassembly on the base substrate, the optical IO subassembly coupled to the SoC by a die-to-die (D2D) interface; with
the optical IO subassembly comprising an optical IO IC mounted to the base substrate, optoelectronic (OE) device arrays bonded to a surface of the optical IO IC away from the base substrate, and, over the OE device arrays, coupling optics to increase optical coupling efficiency into optical fibers, and an optical window layer.

2. The multi-chip package with a vertical optical interface of claim 1, wherein the optical window layer is over the coupling optics.

3. The multi-chip package with a vertical optical interface of claim 2, wherein the D2D interface traverses the base substrate.

4. The multi-chip package with a vertical optical interface of claim 2, wherein the OE device arrays comprise arrays of microLEDs and/or photodetectors.

5. The multi-chip package with a vertical optical interface of claim 2, wherein the OE device arrays comprise arrays of microLEDs.

6. The multi-chip package with a vertical optical interface of claim 5, wherein the optical IO IC includes LED driver circuitry for driving the microLEDs.

7. The multi-chip package with a vertical optical interface of claim 6, wherein the SoC and the optical IO IC are in a layer of molding compound.

8. The multi-chip package with a vertical optical interface of claim 7, wherein the optical window layer comprises an optical microchannel window.

9. The multi-chip package with a vertical optical interface of claim 8, wherein the optical microchannel window comprises fiber cores.

10. The multi-chip package with a vertical optical interface of claim 8, wherein the optical microchannel window duplicates an optical distribution presented at one face of the optical microchannel window at another face of the optical microchannel window.

11. The multi-chip package with a vertical optical interface of claim 8, wherein the optical microchannel window comprises cores on a grid matching a grid of the microLEDs.

12. The multi-chip package with a vertical optical interface of claim 7, wherein the optical window layer comprises a clear uniform optical medium.
